(19) United States
(12) Patent Application Publication
(10) Pub. No.: US 2020/0219789 A1
(43) Pub. Date: Jul. 9, 2020

(54) THERMAL MANAGEMENT SOLUTIONS FOR INTEGRATED CIRCUIT ASSEMBLIES USING PHASE CHANGE MATERIALS

(71) Applicant: Intel Corporation, Santa Clara, CA (US)

(72) Inventors: Aastha Uppal, Chandler, AZ (US); Je-Young Chang, Phoenix, AZ (US); Javed Shaikh, Bangalore (IN); Divya Mani, Chandler, AZ (US); Weihua Tang, Chandler, AZ (US)

(73) Assignee: Intel Corporation, Santa Clara, CA (US)

(21) Appl. No.: 16/241,108

(22) Filed: Jan. 7, 2019

(51) Int. Cl. H01L 23/427; H01L 23/522; H01L 21/48; H01L 23/00

(52) U.S. Cl. CPC H01L 23/427; H01L 23/5226; H01L 21/4882; H01L 2924/14; H01L 24/17; H01L 24/73; H01L 24/09

(57) ABSTRACT

An integrated circuit structure may be formed using a phase change material to substantially fill at least one chamber within the integrated circuit assembly to increase thermal capacitance. The integrated circuit assembly may comprise a substrate, at least one integrated circuit device electrically attached to the substrate, a heat dissipation device, a thermal interface material between the integrated circuit device and the heat dissipation device, a chamber defined by the heat dissipation device, the substrate, and the integrated circuit device, and a phase change material within the chamber.

### TECHNICAL FIELD

Embodiments of the present description generally relate to the removal of heat from integrated circuit assemblies, and, more particularly, to thermal management solutions for integrated circuit assemblies using phase change materials.

### BACKGROUND

Higher performance, lower cost, increased miniaturization, and greater packaging density of integrated circuits within integrated circuit devices are ongoing goals of the electronics industry. As these goals are achieved, integrated circuit packages become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. This issue becomes even more critical when the integrated circuit package includes a microprocessor utilizing turbo boost technology (also referred to as “dynamic overclocking”), which temporarily increases the microprocessor's operating frequency when demanding tasks are running. Although, this dynamic overclocking is transient, the heat generated may exceed the capability for heat removal of the thermal solution in the integrated circuit package.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly having a phase change material substantially filling at least one chamber within the integrated circuit assembly to increase thermal capacitance, wherein the at least one chamber is defined by a heat dissipation device attached to a first substrate, according to an embodiment of the present description.

FIG. 2 is a top plan view along line 2-2 of FIG. 1, according to one embodiment of the present description.

FIG. 3 is a side cross-sectional view of an integrated circuit assembly having a phase change material substantially filling at least one chamber within the integrated circuit assembly to increase thermal capacitance, wherein the at least one chamber is defined by a heat dissipation device attached to a second substrate, according to an embodiment of the present description.

FIG. 4 is a top plan view along line 4-4 of FIG. 3, according to one embodiment of the present description.

FIG. 5 is a side cross-sectional view of an integrated circuit assembly having a first phase change material substantially filling a first chamber within the integrated circuit assembly and a second phase change material substantially filling a second chamber within the integrated circuit assembly, according to an embodiment of the present description.

FIG. 6 is a top plan view along line 6-6 of FIG. 5, according to one embodiment of the present description.

FIG. 7 is a flow diagram of a method of fabricating an integrated circuit assembly, according to one embodiment of the present description.

FIG. 8 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description may include using a phase change material to substantially fill at least one chamber within an integrated circuit assembly to increase thermal capacitance. In one embodiment of the present description, the integrated circuit assembly may comprise a first substrate having a first surface, at least one integrated circuit device electrically attached to the first substrate, wherein the at least one integrated circuit device comprises a first surface, an opposing second surface, and at least one side extending between the first surface and the second surface of the at least one integrated circuit device, a heat dissipation device comprising a main body having a first surface, a thermal interface material between the second surface of the at least one integrated circuit device and the first surface of the main body of the heat dissipation device, a first chamber defined by the first surface of the main body of the heat dissipation device, the first surface of the first substrate, and the at least one side of the at least one integrated circuit device, and a first phase change material within the first chamber.

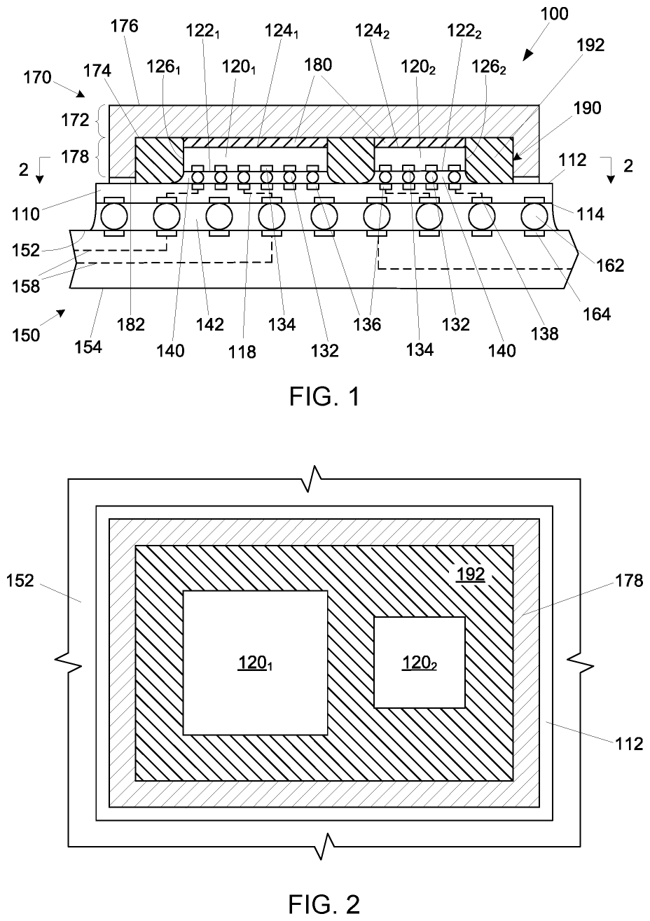

FIG. 1 illustrates an integrated circuit assembly 100 having at least one integrated circuit device (illustrated as a first integrated circuit device 120₁ and a second integrated circuit device 120₂) electrically attached to a first substrate 110 in a configuration generally known as a flip-chip or controlled collapse chip connection (“C4”) configuration, according to an embodiment of the present description.

The first substrate 110 may be any appropriate structure, including, but not limited to, an interposer. The first substrate 110 may have a first surface 112 and an opposing second surface 114. The first substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The first substrate 110 may further include conductive routes 118 or “metallization” (shown in dashed lines) extending through the first substrate 110. As will be understood to those skilled in the art, the conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the first substrate 110 may be a cored substrate or a coreless substrate.

The first integrated circuit device 120₁ and the second integrated circuit device 120₂ may be any appropriate device, including, but not limited to, a microprocessor, a chipset, a graphics device, a wireless device, a memory device, an application specific integrated circuit, combinations thereof, stacks thereof, or the like. As shown, the first integrated circuit device 120₁ may have a first surface 122₁, an opposing second surface 124₁, and at least one side 126₁ extending between the first surface 122₁ and the second surface 124₁. The second integrated circuit device 120₂ may also have a first surface 122₂, an opposing second surface 124₂, and at least one side 126₂ extending between the first surface 122₂ and the second surface 124₂.

In an embodiment of the present description, the first integrated circuit device 120₁ and the second integrated circuit device 120₂ may be electrically attached to the first substrate 110 with a plurality of device-to-substrate interconnects 132. In one embodiment of the present description, the device-to-substrate interconnects 132 may extend between bond pads 136 on the first surface 112 of the first substrate 110 and bond pads 134 on the first surface 122₁ of the integrated circuit device 120₁ and on the first surface 122₂ of the second integrated circuit device 120₂. The device-to-substrate interconnects 132 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys).

The bond pads 134 may be in electrical communication with integrated circuitry (not shown) within their respective integrated circuit devices, i.e. the first integrated circuit device 120₁ and the second integrated circuit device 120₂. The bond pads 136 on the first surface 112 of the first substrate 110 may be in electrical contact with the conductive routes 118. The conductive routes 118 may extend through the first substrate 110 and be connected to bond pads 138 on the second surface 114 of the first substrate 110. As will be understood to those skilled in the art, the first substrate 110 may reroute a fine pitch (center-to-center distance between the bond pads) of the integrated circuit device bond pads 136 to a relatively wider pitch of the bond pads 138 on the second surface 114 of the first substrate 110.

An electrically-insulating first underfill material 140 may be disposed between the first integrated circuit device 120₁ and the first substrate 110, and between the second integrated circuit device 120₂ and the first substrate 110. The first underfill material 140 may be used to overcome the mechanical stress issues that can arise from thermal expansion mismatch between the first substrate 110 and the integrated circuit devices 120₁ and 120₂.

The integrated circuit assembly 100 may further include a second substrate 150, wherein the first substrate 110 is electrically attached thereto. The second substrate 150 may be any appropriate structure, including, but not limited to, a motherboard. The second substrate 150 may have a first surface 152 and an opposing second surface 154. The second substrate 150 may be fabricated in a similar manner and with similar materials as discussed with regard to the first substrate 110. The second substrate 150 may further include conductive routes 158 or “metallization” (shown in dashed lines) extending through the second substrate 150. As will be understood to those skilled in the art, the conductive routes 158 of the second substrate 150 may provide electrical communication pathways to external components (not shown). As will be understood to those skilled in the art, the conductive routes 158 may be a combination of conductive traces (not shown) and conductive vias (not shown) extending through the plurality of dielectric material layers (not shown). These conductive traces and conductive vias are well known in the art and are not shown in FIG. 1 for purposes of clarity. As will be further understood to those skilled in the art, the second substrate 150 may be a cored substrate or a coreless substrate.

In an embodiment of the present description, the first substrate 110 may be electrically attached to the second substrate 150 with a plurality of substrate-to-substrate interconnects 162. In one embodiment of the present description, the substrate-to-substrate interconnects 162 may extend between the bond pads 138 on the second surface 114 of the first substrate 110 and bond pads 164 on the first surface 152 of the second substrate 150. The substrate-to-substrate interconnects 162 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys).

An electrically-insulating second underfill material 142 may be disposed between the first substrate 110 and the second substrate 150. The second underfill material 142 may be used to overcome the mechanical stress issues that can arise from thermal expansion mismatch between the first substrate 110 and the second substrate 150.

As further illustrated in FIG. 1 and according to one embodiment of the present description, a heat dissipation device 170, such as an integrated heat spreader, may be attached to the first surface 112 of the first substrate 110. In one embodiment of the present description, the heat dissipation device 170 may comprise a main body 172, having a first surface 174 and an opposing second surface 176, and at least one boundary wall 178 extending from the first surface 174 of the main body 172 of the heat dissipation device 170. The at least one boundary wall 178 may be attached or sealed to the first surface 112 of the first substrate 110 with an attachment adhesive or sealant layer 182. The heat dissipation device 170 may be made of any appropriate thermally conductive material, including, but not limited to at least one metal material and alloys of more than one metal, or highly doped glass or highly conductive ceramic material, such as aluminum nitride. In an embodiment of the present description, the heat dissipation device 170 may comprise copper, nickel, aluminum, alloys thereof, laminated metals including coated materials (such as nickel coated copper), and the like.

As illustrated in FIG. 1, the heat dissipation device 170 may be a single material throughout, such as when the heat dissipation device 170 including the heat dissipation boundary wall 178 is formed by a single process step, including but not limited to, stamping, skiving, molding, and the like. However, embodiments of the present description may also include heat dissipation device 170 made of more than one component. For example, the heat dissipation device boundary wall 178 may be formed separately from the main body 172, then attached together to form the heat dissipation device 170. In one embodiment shown in FIG. 2, the boundary wall 178 may be a single “picture frame” structure surrounding the first integrated circuit device 120₁ and the second integrated circuit device 120₂.

The attachment adhesive or sealant layer 182 may be any appropriate material, including, but not limited to, silicones (such as polydimethylsiloxane), epoxies, and the like. It is understood that the boundary wall 178 not only secures the heat dissipation device 170 to the substrate 140, but also maintains a desired distance (e.g. bond line thickness) between the first surface 174 of the heat dissipation device 170 and second surfaces 124₁, 124₂ of the integrated circuit devices 120₁, 120₂, respectively.

The first surface 174 of the main body 172 of the heat dissipation device 170 may be thermally coupled with the second surface 124₁ of the first integrated circuit device 120₁ and the second surface 124₂ of the second integrated circuit device 120₂ with a thermal interface material 180. In various embodiment of the present description, the thermal interface material 180 may be any known material, including, but not limited to, a thermal grease, a thermal gap pads, a polymer, an epoxy filled with high thermal conductivity fillers, such as metal particles or silicon particles, and the like. In one embodiment of the present description, the thermal interface material 180 may be a phase change material. A phase change material is a substance with a high heat of fusion, which, when it melts and solidifies, is capable of storing and releasing large amounts of thermal energy. In an embodiment of the present description, the phase change material may include, but not limited to, nonadecane, decanoic (capric) acid, eicosane, dodecanoic (lauric) acid, docosane, paraffin wax, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof.

Although known thermal interface material are able to achieve a desired thermal performance with a specific heat dissipation device design to ensure junction temperatures are sustained with a specific thermal limit, as previously discussed, there are challenges with regard to transient performance due to high power densities and turbo boost technology, which can result in the junction temperature not being sustained within its limit.

As shown in FIG. 1, a chamber 190 may be substantially defined by the first surface 174 of the main body 172 of the heat dissipation device 170, the boundary wall 178 of the heat dissipation device 170, the first surface 112 of the first substrate 110, and the components on the first substrate 110 surrounded by the boundary wall 178 (e.g. integrated circuit devices 110₁ and 110₂). In known integrated circuit assemblies, the chamber 190 is essentially empty. In an embodiment of the present description, the chamber 190 may be substantially filled with a phase change material 192. The phase change material 192 may include, but not limited to, nonadecane, decanoic (capric) acid, eicosane, dodecanoic (lauric) acid, docosane, paraffin wax, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof. In one embodiment of the present description, the thermal interface material 180 and the phase change material 192 may be the same material.

The addition of the phase change material 192 within the chamber 190 may increase the thermal capacitance (thermal energy storage) of the integrated circuit assembly, which may allow for thermal performance regardless of high power densities and turbo boosting.

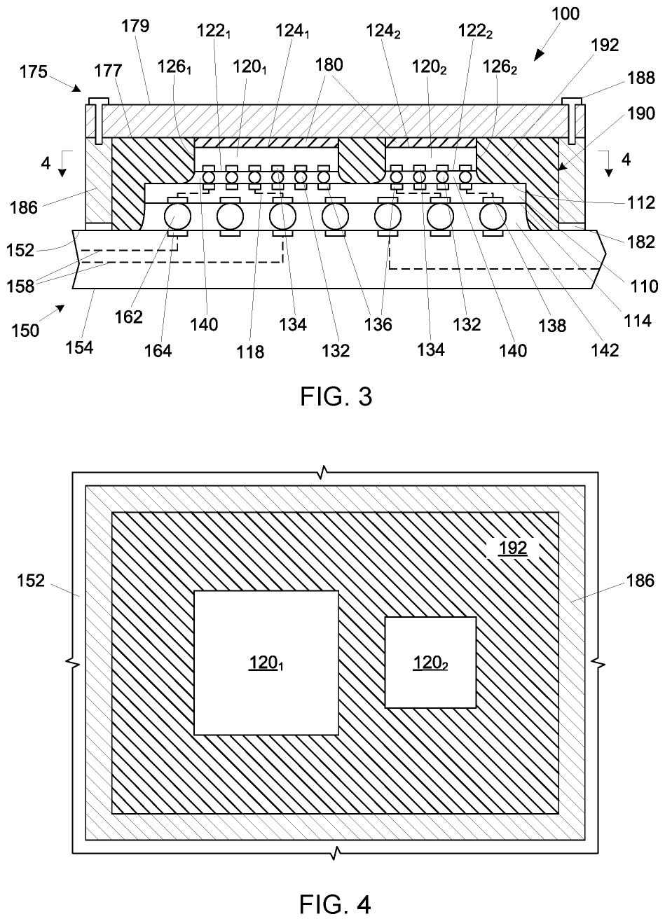

In a further embodiment of the present description, as illustrated in FIG. 3, a heat dissipation device 175, having a first surface 177 and an opposing second surface 179, may be attached to the first surface 152 of the second substrate 150. The heat dissipation device 175 may be attached with at least one system stand-off structure 186 extending from the first surface 152 of the second substrate 150. The system stand-off structure 186 may be attached to the first surface 152 of the second substrate 150 with the attachment adhesive or sealant layer 182. The heat dissipation device 175 may be attached with at least one system stand-off structure 186 by any appropriate means, including, but not limited to, an adhesive (not shown) or a bolt/screw 188. In an embodiment of the present description, as shown in FIG. 4, the system stand-off structure 186 may be a single “picture frame” structure surrounding the first integrated circuit device 120₁, the second integrated circuit device 120₂, and the first substrate 110. As shown in FIG. 3, the chamber 190 may be substantially defined by the first surface 177 of the heat dissipation device 175, the system stand-off structure 186, the first surface 112 of the first substrate 110, the first surface 152 of the second substrate 150, and the components on the first substrate 110 (e.g. integrated circuit devices 110₁ and 110₂). As with the embodiment shown in FIG. 1, the chamber 190 may be substantially filled with the phase change material 192. It is understood that, rather than the integrated heat spreader-type heat dissipation device 170 shown in FIG. 1, the heat dissipation device 175 of FIG. 3 can be any shape or form.

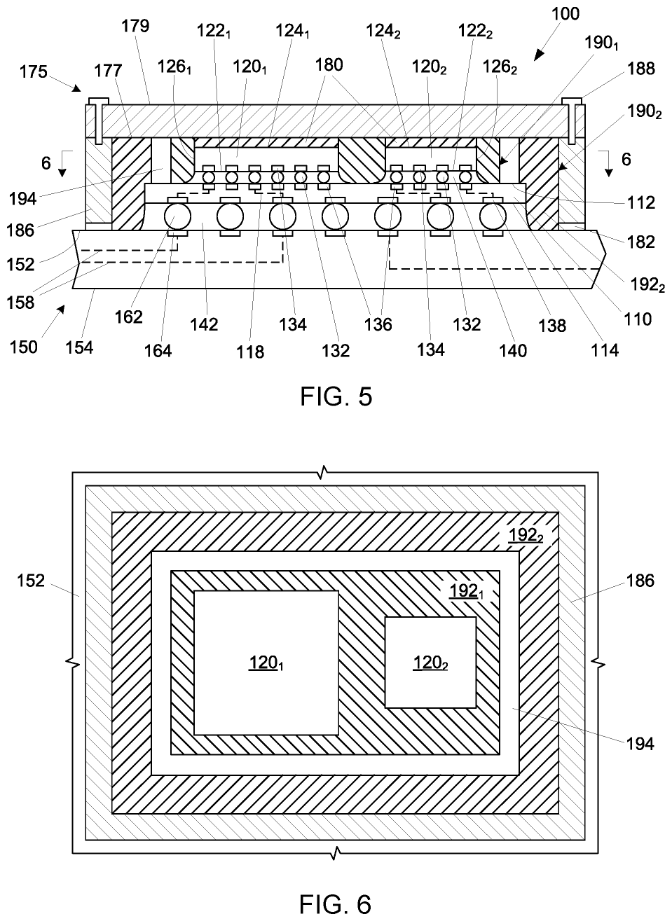

In still a further embodiment of the present description, as shown in FIGS. 5 and 6, the integrated circuit assembly 100 may further include a stiffener 194 disposed between the first surface 177 of the heat dissipation device 175 and the first surface 112 of the first substrate 110. The stiffener 194 may be used to improve the structural integrity of the integrated circuit assembly 100. In one embodiment of the present description, as shown in FIG. 6, the stiffener 194 may be a single “picture frame” structure surrounding the first integrated circuit device 120₁ and the second integrated circuit device 120₂. As shown in FIG. 5, a first chamber 190₁ may be substantially defined by the first surface 177 of the heat dissipation device 175, the stiffener 194, the first surface 112 of the first substrate 110, and the components on the first substrate 110 (e.g. integrated circuit devices 110₁ and 110₂). The first chamber 190₁ may be substantially filled with a first phase change material 192₁. As further shown in FIG. 5, a second chamber 190₂ may be substantially defined by the first surface 177 of the heat dissipation device 175, the system stand-off structure 186, the first surface 152 of the second substrate 150, and the stiffener 194. The second chamber 190₂ may be substantially filled with a second phase change material 192₂.

In one embodiment of the present description, the first phase change material 192₁ and the second phase change material 192₂ may be the same material. In another embodiment of the present description, the first phase change material 192₁ and the second phase change material 192₂ may be different from one another. As will be understood, the first phase change material 192₁ and the second phase change material 192₂ may each be specifically selected to achieve desired thermal management goals within the integrated circuit assembly 100.

It is understood that additional thermal management devices (not shown) may be attached to the second surfaces 174, 179 of the heat dissipation devices 170, 175, respectively, to enhance heat removal. Such additional thermal management devices may include, but are not limited to, heat pipes, high surface area dissipation structures with a fan (such as a structure having fins or pillars/columns formed in a thermally conductive structure), liquid cooling devices, and the like, as will be understood to those skilled in the art.

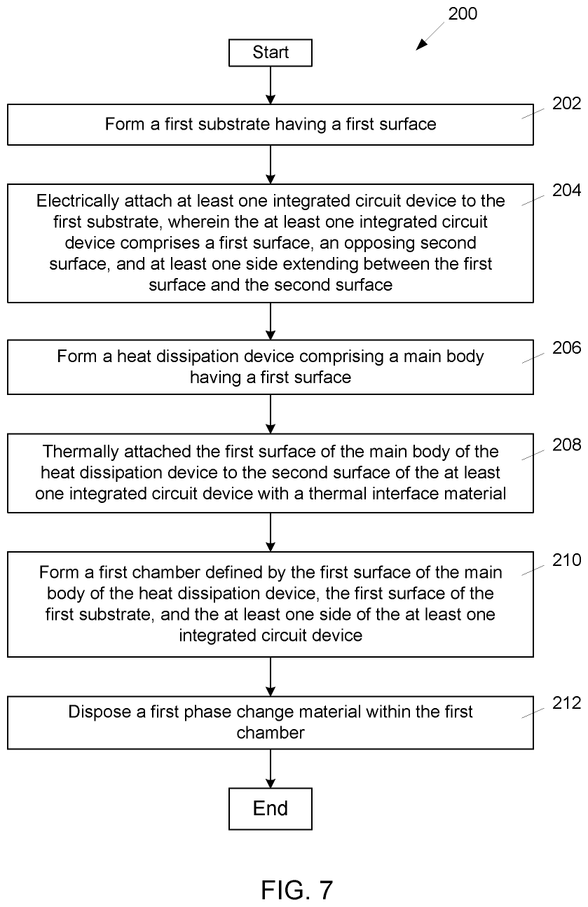

FIG. 7 is a flow chart of a process 200 of fabricating an integrated circuit assembly according to an embodiment of the present description. As set forth in block 202, a first substrate having a first surface may be formed. At least one integrated circuit device may be electrically attached to the first substrate, wherein the at least one integrated circuit device comprises a first surface, an opposing second surface, and at least one side extending between the first surface and the second surface of the at least one integrated circuit device, as set forth in block 204. As set forth in block 206, a heat dissipation device comprising a main body having a first surface may be formed. The first surface of the main body of the heat dissipation device may be thermally attached to the second surface of the at least one integrated circuit device with a thermal interface material, as set forth in block 208. As set forth in block 210, a first chamber may be formed which is defined by the first surface of the main body of the heat dissipation device, the first surface of the first substrate, and the at least one side of the at least one integrated circuit device. A first phase change material may be disposed within the first chamber, as set forth in block 212.

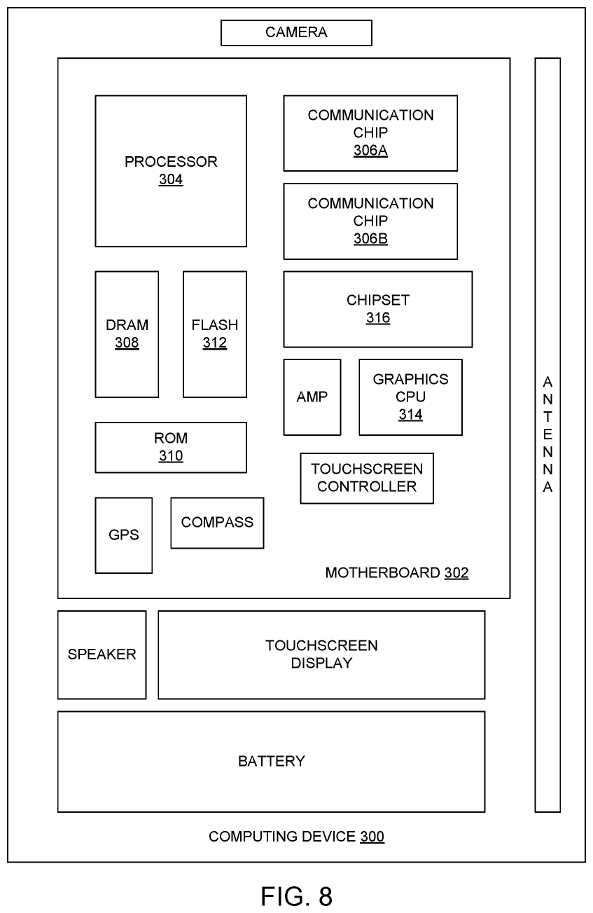

FIG. 8 illustrates an electronic or computing device 300 in accordance with one implementation of the present description. The computing device 300 may include a housing 301 having a board 302 disposed therein. The board 302 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G , 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an integrated circuit structure comprising a first substrate having a first surface; at least one integrated circuit device electrically attached to the first substrate, wherein the at least one integrated circuit device comprising a first surface, an opposing second surface, and at least one side extending between the first surface and the second surface of the at least one integrated circuit device; a heat dissipation device comprising a main body having a first surface; a thermal interface material between the second surface of the at least one integrated circuit device and the first surface of the main body of the heat dissipation device; a first chamber defined by the first surface of the main body of the heat dissipation device, the first surface of the first substrate, and the at least one side of the at least one integrated circuit device; and a first phase change material within the first chamber.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-8. The subject matter may be applied to other integrated circuit devices and assembly applications, as well as any appropriate electronic application, as will be understood to those skilled in the art.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An integrated circuit assembly, comprising:
a first substrate having a first surface;
at least one integrated circuit device electrically attached to the first substrate, wherein the at least one integrated circuit device comprises a first surface, an opposing second surface, and at least one side extending between the first surface and the second surface of the at least one integrated circuit device;
a heat dissipation device comprising a main body having a first surface;
a thermal interface material between the second surface of the at least one integrated circuit device and the first surface of the main body of the heat dissipation device;
a first chamber defined by the first surface of the main body of the heat dissipation device, the first surface of the first substrate, and the at least one side of the at least one integrated circuit device; and
a first phase change material within the first chamber.

2. The integrated circuit assembly of claim 1, wherein the thermal interface material comprises a phase change material.

3. The integrated circuit assembly of claim 1, wherein the heat dissipation device includes a boundary wall extending from the first surface of the main body of the heat dissipation device, and wherein the boundary wall is attached to the first substrate.

4. The integrated circuit assembly of claim 1, further including a second substrate having a first surface, wherein the first substrate is electrically attached to the second substrate, and wherein the heat dissipation device is attached to the second substrate.

5. The integrated circuit assembly of claim 4, wherein the heat dissipation device includes a system stand-off between the first surface of the main body of the heat dissipation device and the second substrate.

6. The integrated circuit assembly of claim 4, further comprising a stiffener extending between the first surface of the main body of the heat dissipation and the first surface of the first substrate.

7. The integrated circuit assembly of claim 5, wherein the first chamber is defined by the first surface of the main body of the heat dissipation device, the first surface of the first substrate, the at least one side of the at least one integrated circuit device, and the stiffener; and wherein a second chamber is defined by the first surface of the main body of the heat dissipation device, the first surface of the second substrate, and the stiffener.

8. The integrate circuit assembly of claim 7, further including a second phase change material within the second chamber.

9. A method of fabricating an integrated circuit assembly, comprising:
forming a first substrate having a first surface;
electrically attaching at least one integrated circuit device to the first substrate, wherein the at least one integrated circuit device comprising a first surface, an opposing second surface, and at least one side extending between the first surface and the second surface of the at least one integrated circuit device;
forming a heat dissipation device comprising a main body having a first surface;
thermally attaching the first surface of the main body of the heat dissipation device to the second surface of the at least one integrated circuit device with a thermal interface material;
forming a first chamber defined by the first surface of the main body of the heat dissipation device, the first surface of the first substrate, and the at least one side of the at least one integrated circuit device; and
disposing a first phase change material within the first chamber.

10. The method of claim 9, wherein thermally attaching the first surface of the heat dissipation device to the at least one integrated circuit device with a thermal interface material comprises thermally attaching the first surface of the heat dissipation device to the at least one integrated circuit device with a phase change material.

11. The method of claim 9, wherein forming the heat dissipation device includes forming a boundary wall extending from the first surface of the main body of the heat dissipation device, and further comprising attaching the boundary wall to the first substrate.

12. The method of claim 9, further including:
forming a second substrate having a first surface;
electrically attaching the first substrate to the second substrate; and
attaching the heat dissipation device to the second substrate.

13. The method of claim 12, wherein attaching the heat dissipation device to the second substrate comprises:
attaching a system stand-off structure to the second substrate; and
attaching the first surface of the main body of heat dissipation device to the system stand-off structure.

14. The method of claim 12, further comprising forming a stiffener extending between the first surface of the main body of the heat dissipation and the first surface of the first substrate.

15. The method of claim 12, wherein forming the first chamber comprises forming the first chamber defined by the first surface of the main body of the heat dissipation device, the first surface of the first substrate, the at least one side of the at least one integrated circuit device, and the stiffener; and further comprising forming a second chamber defined by the first surface of the main body of the heat dissipation device, the first surface of the second substrate, and the stiffener.

16. The method of claim 15, further including disposing a second phase change material within the second chamber.

17. An electronic system, comprising:
a housing;
a motherboard disposed within the housing;
an integrated circuit package electrically attached to a first surface of the motherboard, wherein the integrated circuit package comprises:
a first substrate having a first surface;
at least one integrated circuit device electrically attached to the first substrate, wherein the at least one integrated circuit device comprising a first surface, an opposing second surface, and at least one side extending between the first surface and the second surface of the at least one integrated circuit device;
a heat dissipation device comprising a main body having a first surface;
a thermal interface material between the second surface of at least one integrated circuit device and the first surface of the main body of the heat dissipation device;
a first chamber defined by the first surface of the main body of the heat dissipation device, the first surface of the first substrate, and the at least one side of the at least one integrated circuit device; and
a first phase change material within the first chamber.

18. The electronic system of claim 17, wherein the thermal interface material comprises a phase change material.

19. The electronic system of claim 17, wherein the heat dissipation device includes a boundary wall extending from the first surface of the main body of the heat dissipation device, and wherein the boundary wall is attached to the first substrate.

20. The electronic system of claim 17, wherein the heat dissipation device is attached to the motherboard.

21. The electronic system of claim 20, further including a system stand-off structure extending from the first surface of the main body of the heat dissipation device and the first surface of the motherboard.

22. The electronic system of claim 20, further comprising a stiffener extending between the first surface of the main body of the heat dissipation and the first surface of the first substrate.

23. The electronic system of claim 22, wherein the first chamber is defined by the first surface of the main body of the heat dissipation device, the first surface of the first substrate, the at least one side of the at least one integrated circuit device, and the stiffener; and wherein a second chamber is defined by the first surface of the main body of the heat dissipation device, the first surface of the motherboard, and the stiffener.

24. The electronic system of claim 23, further including a second phase change material within the second chamber.
